(19) United States
(12) Patent Application Publication
(10) Pub. No.: US 2011/0140712 A1
(43) Pub. Date: Jun. 16, 2011

(54) METHOD OF DETERMINING APPLICATION LIMIT OF ELECTROSTATIC CHUCK

(76) Inventor: Nagahiro Inoue, Shizuoka (JP)

(21) Appl. No.: 13/057,292

(22) PCT Filed: Aug. 17, 2009
(86) PCT No.: PCT/JP2009/064414

§ 371 Date: Feb. 23, 2011

(30) Foreign Application Priority Data
Aug. 20, 2008 (JP) 2008-211476

(51) Int. Cl. G01R 31/02

(52) U.S. Cl. 324/537

(57) ABSTRACT

There is provided a method of determining an application limit of an electrostatic chuck, in which method a determination can be accurately made as to whether the electrostatic chuck has reached the application limit or not. The electrostatic chuck has a first electrode and a second electrode, and a coating layer made of a dielectric material to cover both the electrodes. By applying a voltage from a power supply between the first and the second electrodes, a to-be-processed substrate that is mounted on a surface of the coating layer is attracted. A current value that flows between the first and the second electrodes in a state of attracting the to-be-processed substrate is detected by an ammeter. When the detected current value has exceeded a predetermined threshold value, a determination is made that the electrostatic chuck has reached the application limit. The threshold value is set to different values depending on various kinds of to-be-processed substrates whose rear surfaces coming into contact with the electrostatic chuck have different resistance values.

### TECHNICAL FIELD

The present invention relates to a method of determining an application limit of an electrostatic chuck which is used in holding a to-be-processed substrate when predetermined processing such as sputtering and the like is performed on the to-be-processed substrate.

### BACKGROUND ART

As an electrostatic chuck, there is conventionally known one which has a first electrode and a second electrode, and a coating layer which is made up of a dielectric material to cover the electrodes. By applying a voltage between the first and the second electrodes, a substrate to be processed (hereinafter referred to as a to-be-processed substrate) that is mounted on the surface of the coating layer is attracted (see, e.g., patent document 1). In case the to-be-processed substrate is an insulating substrate, the to-be-processed substrate will be attracted to the surface of the chuck plate due to the gradient force that is generated by applying a voltage between the first and the second electrodes. In case the to-be-processed substrate is a non-insulating substrate, the to-be-processed substrate will be attracted to the chuck plate due to the Coulomb force that is generated by applying a voltage between the first and the second electrodes.

By the way, in case the to-be-processed substrate that is attracted to the electrostatic chuck is heated and cooled, due to difference in thermal expansion between that of the to-be-processed substrate and that of the electrostatic chuck, the coating layer will be scratched by the to-be-processed substrate, thereby gradually wearing out. Therefore, it is conventionally so arranged that, when the number of the to-be-processed substrates that were attracted by the electrostatic chuck has reached a predetermined limit of numbers of handling, a determination is made that the electrostatic chuck has reached an application limit (i.e., a limit beyond which the electrostatic chuck cannot be put to a satisfactory use), thereby replacing the electrostatic chuck.

However, even though the number of the to-be-processed substrates has reached the limit of numbers of handling by the electrostatic chuck, there are cases where the coating layer has not been worn out so much. Therefore, it is desired to determine the application limit of the electrostatic chuck more accurately in order to reduce the frequency of replacing the electrostatic chuck and improve the productivity.

### PRIOR ART DOCUMENT

### Patent Document

Patent Document 1: JP-A-2004-31502

### SUMMARY OF THE INVENTION

### Problems to be Solved by the Invention

In view of the above points, this invention has a problem of providing a method of determining an application limit of an electrostatic chuck, in which method it can be accurately determined whether the electrostatic chuck has reached an application limit or not.

### Means for Solving the Problems

In order to solve the above-mentioned problems, this invention is a method of determining an application limit of an electrostatic chuck. The electrostatic chuck comprises: a first electrode and a second electrode; and a coating layer made of a dielectric material to cover both the first and the second electrodes so that a to-be-processed substrate mounted on a surface of the coating layer is attracted by applying a voltage between the first and the second electrodes. The method comprises: detecting a current value that flows between the first and the second electrodes in a state in which the to-be-processed substrate is attracted; and determining that the electrostatic chuck has reached the application limit when the detected current value has exceeded a predetermined threshold value. The threshold value is set to different values depending on various kinds of to-be-processed substrates whose rear surfaces coming into contact with the electrostatic chuck have different resistance values.

The current value that flows between the first and the second electrodes at the time of attracting the to-be-processed substrate, gradually increases with the wear of the coating layer. Therefore, this current value can be a parameter to show the degree of wear of the coating layer. Depending on whether the current value has exceeded the threshold value or not, a determination can be made as to whether the wear of the coating layer has reached a limit or not, i.e., whether the electrostatic chuck has reached the application limit or not. However, this current value varies also with the resistance value of that rear surface of the substrate which comes into contact with the electrostatic chuck, and the smaller becomes the resistance value of the rear surface of the substrate, the larger becomes the current value. Therefore, if the threshold value is univocally decided, a to-be-processed substrate having a small resistance value of the rear surface of the substrate may be wrongly determined to have reached the application limit even though the electrostatic chuck has actually not reached the application limit. In this invention, on the other hand, the threshold values have been set to different values depending on the various resistance values on the rear surfaces of the substrates. As a result, accurate determination can be made as to whether the electrostatic chuck has reached the application limit or not.

Once the processing treatments such as sputtering and the like to the to-be-processed substrate begin, the current value that flows between the first and the second electrodes will fluctuate under the influence of the processing treatments. Therefore, in this invention, preferably the current value is one that is detected after the to-be-processed substrate has been attracted but before the processing treatment on the to-be-processed substrate is started. According to this arrangement, determination can be made as to whether the electrostatic chuck has reached the application limit or not based on the current value that is detected in a state in which current fluctuations under the influence of the processing treatments do not take place. Wrong determination attributable to the current fluctuations can thus be prevented.

### BRIEF DESCRIPTION OF THE DRAWINGS

FIG. 1 is a general arrangement showing an apparatus to be used in carrying out the method of this invention.

FIG. 2(a) is a sectional view schematically showing the flow of ESC current in before wear of a coating layer, and FIG. 2(b) is a sectional view schematically showing the flow of ESC current after wear of the coating layer.

FIG. 3 is a graph showing the change in ESC current due to wear in the coating layer.

FIG. 4 is a graph showing the transition of ESC current in one processing cycle of the to-be-processed substrate.

FIG. 5 is a flow chart showing the determination processing according to one embodiment of this invention.

### EMBODIMENTS FOR CARRYING OUT THE INVENTION

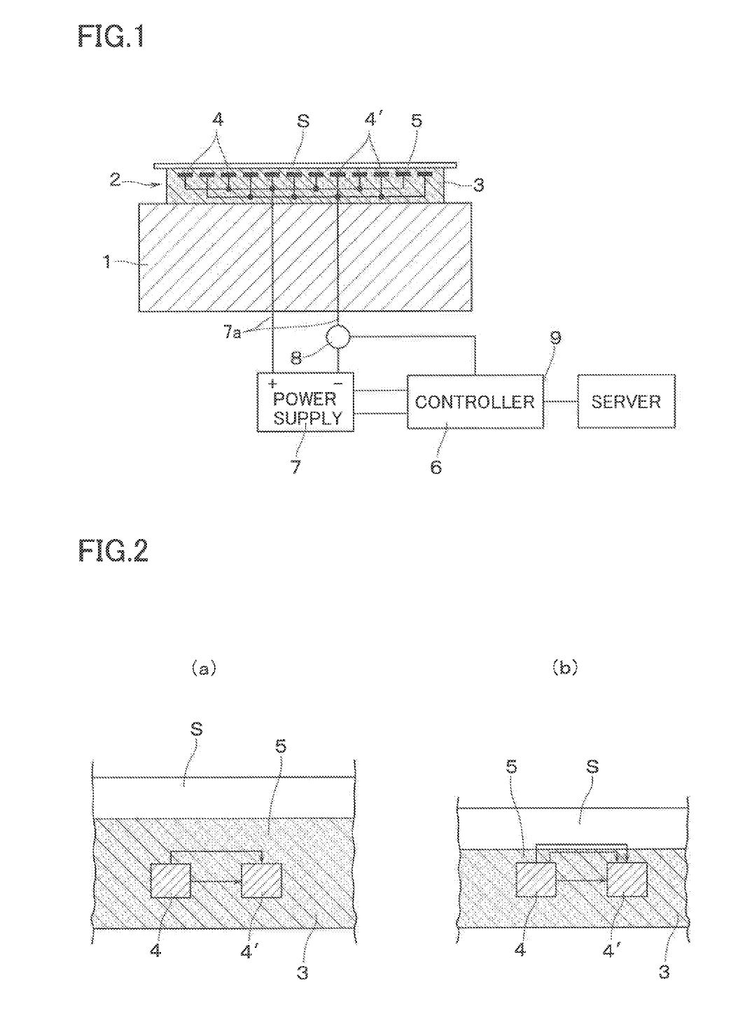

With reference to FIG. 1, reference numeral 1 denotes a stage which is provided inside a vacuum processing chamber (not illustrated). On the stage 1 there is fixed an electrostatic chuck 2 which attracts a to-be-processed substrate S such as a glass substrate and the like. The electrostatic chuck 2 has a chuck plate 3 formed by using, e.g., a ceramic material which is a dielectric material. The chuck plate 3 has buried therein a first electrode 4 and a second electrode 4′. The first electrode 4 and the second electrode 4′ are respectively formed into the shape, e.g., of comb's teeth and are disposed such that the tooth portions come into engagement with each other in a manner to be free from contact with each other.

A DC voltage is applied between the first and the second electrodes 4, 4′ from a power supply 7, which is controlled by a controller 6, through an electric circuit 7a. The electric circuit 7a has interposed therein an ammeter 8 for detecting the value of current that flows through the first and the second electrodes 4, 4′ (this current is hereinafter referred to as ESC current). The data of the ESC current as detected by the ammeter 8 is inputted into the controller 6. The controller 6 has connected thereto an EES (engineering equipment system) server 9.

With reference to FIG. 2(a), the electrostatic chuck 2 is provided with a coating layer 5 which is made of a dielectric material and which covers the first and the second electrodes 4, 4′. It is thus so arranged that, by applying a voltage between the first and the second electrodes 4, 4′, the to-be-processed substrate S which is mounted on the surface of the coating layer 5 gets attracted. Although the coating layer 5 in this embodiment is integral with the chuck plate 3, it may alternatively be so arranged that the coating layer 5 is formed on the chuck plate 3 in a manner to cover both the first and the second electrodes 4, 4′.

When the to-be-processed substrate S is heated by a heating means (not illustrated), the difference in thermal expansion between the electrostatic chuck 2 and the to-be-processed substrate S will cause the coating layer 5 to get scratched by the to-be-processed substrate S and will thus be worn to become thinner. Then, when the thickness of the coating layer 5 becomes smaller than a predetermined wear limit, the electrostatic chuck 2 will no longer be put to use.

It is to be noted here that, as shown in FIG. 2(b), when the coating layer 5 gets thinner, the current tends to flow along the surface of contact between the coating layer 5 and the to-be-processed substrate S, thereby increasing the ESC current. Therefore, the ESC current as detected by the ammeter 8 can serve as a parameter to represent the degree of wear of the coating layer 5. Then, based on whether or not the ESC current has exceeded a predetermined threshold value, a determination can be made as to whether the wear of the coating layer 5 has reached a limit or not, i.e., whether the electrostatic chuck has reached an application limit or not.

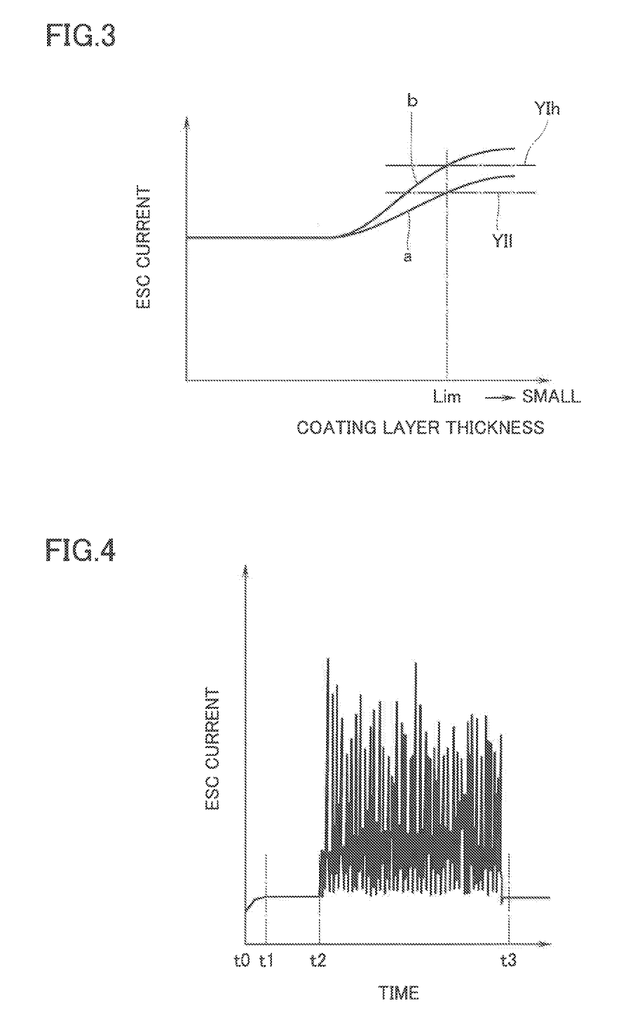

The ESC current, however, varies also with the resistance value on that rear surface of the substrate which comes into contact with the electrostatic chuck 2. In addition, as shown by a line “a” in FIG. 3, in the case of the to-be-processed substrate S having a larger resistance value on the rear surface of the substrate, the increasing rate of the ESC current when the coating layer 5 has worn out becomes smaller. On the other hand, in the case of the to-be-processed substrate S having a smaller resistance value on the rear surface of the substrate, the increasing rate of the ESC current when the coating layer 5 has worn out becomes larger as shown by line b in FIG. 3. It is to be noted here that the resistance value on the rear surface of the substrate varies with the characteristics of a device that has been formed on the rear surface of the substrate even in case the to-be-processed substrate S is made of the same material.

In view of the above point, in this embodiment, the following arrangement has been made, namely, the threshold value is set to different values depending on various to-be-processed substrates having different resistance values on the rear surface of the substrate. In other words, the threshold value is set depending on the kind of the to-be-processed substrate S such that the smaller becomes the resistance value on the rear surface of the substrate, the higher becomes the threshold value. These threshold values are stored in memory in the controller 6. When the ESC current has exceeded the threshold value corresponding to the kind of the to-be-processed substrate S that is being currently attracted, the electrostatic chuck 2 is determined to have reached the application limit. The kind of the to-be-processed substrate S that is attracted by the electrostatic chuck 2 is recognized by the controller 6 by means of an input through the operation of a keyboard.

According to this arrangement, in the case of the to-be-processed substrate S having a large resistance value on the rear surface of the substrate, the threshold value is set to a relatively smaller value YII (see FIG. 3). In the case of the to-be-processed substrate S having a small resistance value on the rear surface of the substrate, the threshold value is set to a relatively higher value YIh. As a result, irrespective of the kind of the to-be-processed substrate S, the electrostatic chuck 2 is determined to have reached the application limit when the thickness of the coating layer 5 has been reduced to the same limit value Lim.

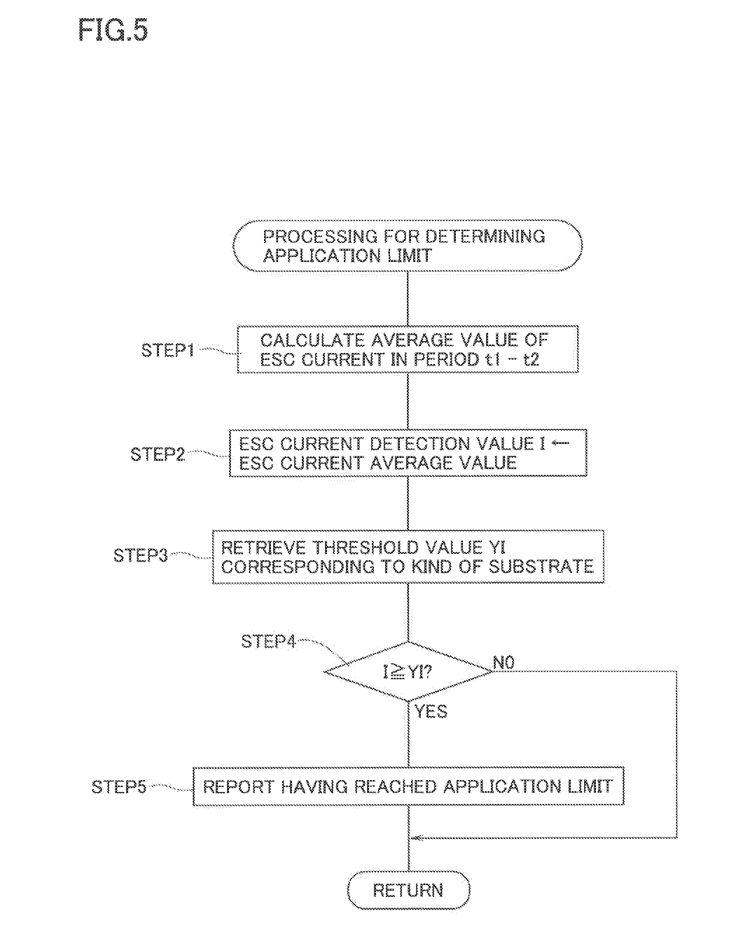

By the way, in subjecting the to-be-processed substrate S to processing treatments, application of the voltage between the first and the second electrodes 4, 4′ is started at a time point of t0 in FIG. 4. The processing treatments such as sputtering and the like to the to-be-processed substrate S are started at a time point t2 which is delayed by a certain period of time from a time point of t1 at which the voltage will have been boosted to a predetermined attraction voltage. The processing treatments will be finished at a time point of t3. FIG. 4 shows the transition of the ESC current. When the sputtering treatment is performed, the ESC current will fluctuate under the influence of the sputtering discharge during the treatment period from t2 to t3.

Therefore, in this embodiment, in order to prevent the wrong determination due to current fluctuations, the processing of determining the application limit of the electrostatic chuck 2 is performed according to the procedures as shown in FIG. 5. In the determining processing, first, the to-be-processed substrate S is attracted. Then, calculation is made of an average value of the ESC currents that have been detected in the period from t1 to t2 that is before starting the treatment to the to-be-processed substrate S (STEP 1). This average value is made to be the ESC current detection value I to be used in the determination at this time (STEP 2). Then, a threshold value YI corresponding to the kind of the to-be-processed substrate S that is being attracted at present is retrieved (STEP 3). Comparison is made between the threshold value YI and the ESC current detection value I (STEP 4). When I becomes equal to or larger than YI, determination is made that the electrostatic chuck 2 has reached the application limit, and a report is made to that effect by means of a buzzer, a lamp, by mail delivery, and the like (STEP 5).

According to this arrangement, a determination can be made as to whether the electrostatic chuck 2 has reached the application limit or not based on the ESC current that is detected in a state which is free from current fluctuations due to effects by the processing treatments. A wrong determination attributable to the current fluctuations can thus be prevented. In addition, since the threshold value YI corresponding to the kind of the to-be-processed substrate S is used, a wrong determination due to the above-mentioned difference in the resistance value on the rear surface of the substrate can also be prevented.

In this embodiment, average values of the ESC currents that have been detected during the period of t1 to t2 are transmitted from the controller 5 to the EES server 9. Then, at the EES server 9 the transition of the above-mentioned average values is stored depending on the kind of the to-be-processed substrate S so that this transition can be outputted in the form of graphs where appropriate.

### DESCRIPTION OF REFERENCE NUMERALS AND CHARACTERS

S to-be-processed substrate
2 electrostatic chuck
4 first electrode
4′ second electrode
5 coating layer
6 controller
7 power supply
8 ammeter

What is claimed is:

1. A method of determining an application limit of an electrostatic chuck, the electrostatic chuck comprising:
a first electrode and a second electrode; and
a coating layer made of a dielectric material to cover both the first and the second electrodes so that a to-be-processed substrate mounted on a surface of the coating layer is attracted by applying a voltage between both the first and the second electrodes, the method comprising:
detecting a current value that flows between the first and the second electrodes at a time of attracting the to-be-processed substrate; and
determining that the electrostatic chuck has reached an application limit when the detected current value has exceeded a predetermined threshold value,
wherein the threshold value is set to different values depending on various kinds of to-be-processed substrates whose rear surfaces coming into contact with the electrostatic chuck have different resistance values.

2. The method of determining an application limit of an electrostatic chuck according to claim 1, wherein the current value is one that is detected after the to-be-processed substrate has been attracted but before the processing treatment on the to-be-processed substrate is started.
